(19) United States
(12) Patent Application Publication
(10) Pub. No.: US 2025/0338565 A1
(43) Pub. Date: Oct. 30, 2025

(54) SEMICONDUCTOR DEVICES AND METHODS OF FABRICATING THE SAME

(71) Applicant: Samsung Electronics Co., Ltd., Suwon-si (KR)

(72) Inventors: DAEWON HA, Seoul (KR); MINGYU KIM, Suwon-si (KR); DOYOUNG CHOI, Hwaseong-si (KR)

(21) Appl. No.: 19/259,506

(22) Filed: Jul. 3, 2025

Related U.S. Application Data
(63) Continuation of application No. 17/398,494, filed on Aug. 10, 2021.

(30) Foreign Application Priority Data
Jan. 20, 2021 (KR) 10-2021-0008083

(51) Int. Cl. H10D 30/67; H01L 21/02; H10D 30/01; H10D 62/10; H10D 64/01

(52) U.S. Cl. CPC H10D 30/6757; H01L 21/02532; H01L 21/0259; H10D 30/031; H10D 30/6713; H10D 30/6735; H10D 30/6741; H10D 62/118; H10D 64/017; H10D 64/018

(57) ABSTRACT

A semiconductor device includes, on a substrate, a channel pattern including semiconductor patterns, which are spaced apart from each other in a first direction perpendicular to a top surface of the substrate, a gate electrode on the channel pattern, the gate electrode disposed on an uppermost semiconductor pattern of the semiconductor patterns and extended into regions between the semiconductor patterns, and a pair of gate spacers disposed on the uppermost semiconductor pattern to cover opposite side surfaces of the gate electrode, respectively. Each semiconductor pattern includes germanium. Each semiconductor pattern includes a pair of first portions vertically overlapped with the pair of gate spacers and a second portion between the pair of first portions. A thickness, in the first direction, of a pair of first portions of the uppermost semiconductor pattern is larger than a thickness, in the first direction, of the second portion of the uppermost semiconductor pattern.

### CROSS-REFERENCE TO RELATED APPLICATION

This U.S. non-provisional patent application is a continuation application of U.S. application Ser. No. 17/398,494 filed on Aug. 10, 2021, which claims priority under 35 U.S.C. § 119 to Korean Patent Application No. 10-2021-0008083, filed on Jan. 20, 2021, in the Korean Intellectual Property Office, the entire contents of each of which are hereby incorporated by reference.

### BACKGROUND OF THE INVENTION

The present disclosure relates to semiconductor devices and methods of fabricating the same, and in particular, to semiconductor devices including field effect transistors and methods of fabricating the same.

A semiconductor device includes an integrated circuit including metal-oxide-semiconductor field-effect transistors (MOSFETs). To meet an increasing demand for the semiconductor device with a small pattern size and a reduced design rule, the MOSFETs are being scaled down. The scale-down of the MOSFETs may lead to deterioration in operation characteristics of the semiconductor device. Accordingly, a variety of studies are being conducted to overcome technical limitations associated with the scale-down of the semiconductor device and to provide high performance semiconductor device.

### SUMMARY

An embodiment of the inventive concept provides a semiconductor device including transistors with an improved mobility property and a method of fabricating the same.

An embodiment of the inventive concept provides a highly-integrated semiconductor device and a method of easily fabricating the same.

According to an embodiment of the inventive concept, a semiconductor device may include a channel pattern on a substrate, the channel pattern including a plurality of semiconductor patterns, which are spaced apart from each other in a first direction perpendicular to a top surface of the substrate, a gate electrode on the channel pattern, the gate electrode being disposed on an uppermost semiconductor pattern of the plurality of semiconductor patterns and being extended into regions between the plurality of semiconductor patterns, and a pair of gate spacers disposed on the uppermost semiconductor pattern to cover opposite side surfaces of the gate electrode, respectively. Each of the plurality of semiconductor patterns may include germanium. Each of the plurality of semiconductor patterns may include a pair of first portions, which are vertically overlapped with the pair of gate spacers, respectively, and a second portion between the pair of first portions. A thickness, in the first direction, of a pair of first portions of the uppermost semiconductor pattern may be larger than a thickness, in the first direction, of a second portion of the uppermost semiconductor pattern.

According to an embodiment of the inventive concept, a semiconductor device may include a channel pattern on a substrate, the channel pattern including a plurality of semiconductor patterns, which are spaced apart from each other in a first direction perpendicular to a top surface of the substrate, a gate electrode on the channel pattern, the gate electrode being disposed on an uppermost semiconductor pattern of the plurality of semiconductor patterns and being extended into regions between the plurality of semiconductor patterns, and a pair of gate spacers disposed on the uppermost semiconductor pattern to cover opposite side surfaces of the gate electrode, respectively. The plurality of semiconductor patterns may include the same material. Each of the plurality of semiconductor patterns may include a pair of first portions, which are vertically overlapped with the pair of gate spacers, respectively, and a second portion between the pair of first portions. The pair of first portions of each of the plurality of semiconductor patterns may include germanium.

According to an embodiment of the inventive concept, a method of fabricating a semiconductor device may include forming an active pattern on a substrate, the active pattern including a plurality of sacrificial patterns and a plurality of preliminary semiconductor patterns, which are alternatively stacked in a first direction perpendicular to a top surface of the substrate, removing the plurality of sacrificial patterns to form a plurality of empty regions between the plurality of preliminary semiconductor patterns, forming a germanium layer on the plurality of preliminary semiconductor patterns exposed by the plurality of empty regions, performing a thermal treatment process on the plurality of preliminary semiconductor patterns provided with the germanium layer to convert the plurality of preliminary semiconductor patterns to a plurality of semiconductor patterns, and removing the germanium layer, which remains on the plurality of semiconductor patterns after the converting of the plurality of preliminary semiconductor patterns to the plurality of semiconductor patterns. Each of the plurality of semiconductor patterns may include germanium.

### BRIEF DESCRIPTION OF THE DRAWINGS

FIG. 1 is a plan view illustrating a semiconductor device according to some embodiments of the inventive concept.

FIG. 2 is a sectional view taken along lines I-I′ and II-II′ of FIG. 1.

FIGS. 3A and 3B are enlarged sectional views illustrating portions A1 and B1 of FIG. 2, respectively.

FIGS. 4 to 10 are sectional views, which correspond to the lines I-I′ and II-II′ of FIG. 1 and illustrate a method of fabricating a semiconductor device, according to some embodiments of the inventive concept.

FIG. 11 is a sectional view, which corresponds to the lines I-I′ and II-II′ of FIG. 1 and illustrates a semiconductor device according to some embodiments of the inventive concept.

FIGS. 12A and 12B are enlarged sectional views illustrating portions A2 and B2 of FIG. 11, respectively.

FIGS. 13 to 16 are sectional views, which correspond to the lines I-I′ and II-II′ of FIG. 1 and illustrate a method of fabricating a semiconductor device, according to some embodiments of the inventive concept.

FIG. 17 is a sectional view, which corresponds to the lines I-I′ and II-II′ of FIG. 1 and illustrates a semiconductor device according to some embodiments of the inventive concept.

FIG. 18 is a sectional view, which corresponds to the lines I-I′ and II-II′ of FIG. 1 and illustrates a method of fabricating a semiconductor device, according to some embodiments of the inventive concept.

FIG. 19 is a sectional view, which corresponds to the lines I-I′ and II-II′ of FIG. 1 and illustrates a semiconductor device according to some embodiments of the inventive concept.

FIG. 20 is a sectional view, which corresponds to the lines I-I′ and II-II′ of FIG. 1 and illustrates a method of fabricating a semiconductor device, according to some embodiments of the inventive concept.

### DETAILED DESCRIPTION

Example embodiments of the inventive concepts will now be described more fully with reference to the accompanying drawings, in which example embodiments are shown.

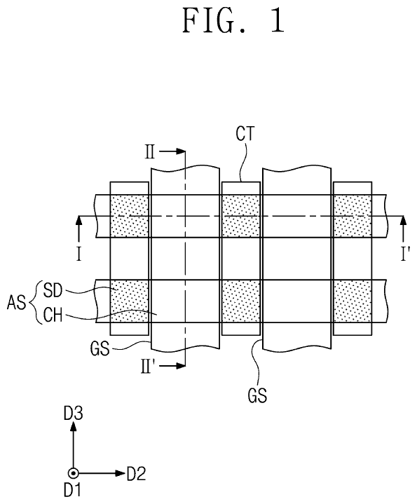

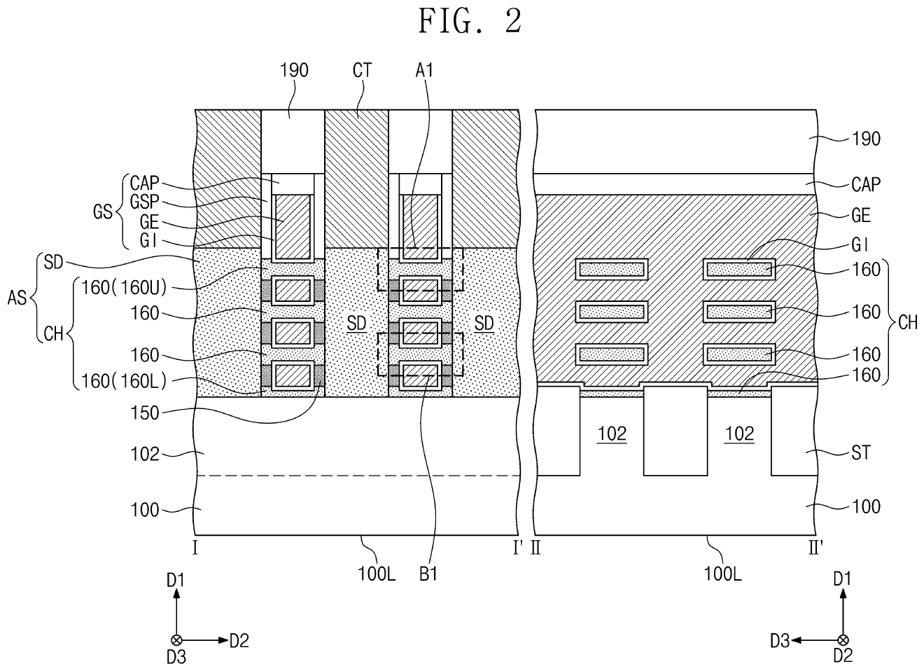

FIG. 1 is a plan view illustrating a semiconductor device according to some embodiments of the inventive concept, and FIG. 2 is a sectional view taken along lines I-I′ and II-II′ of FIG. 1.

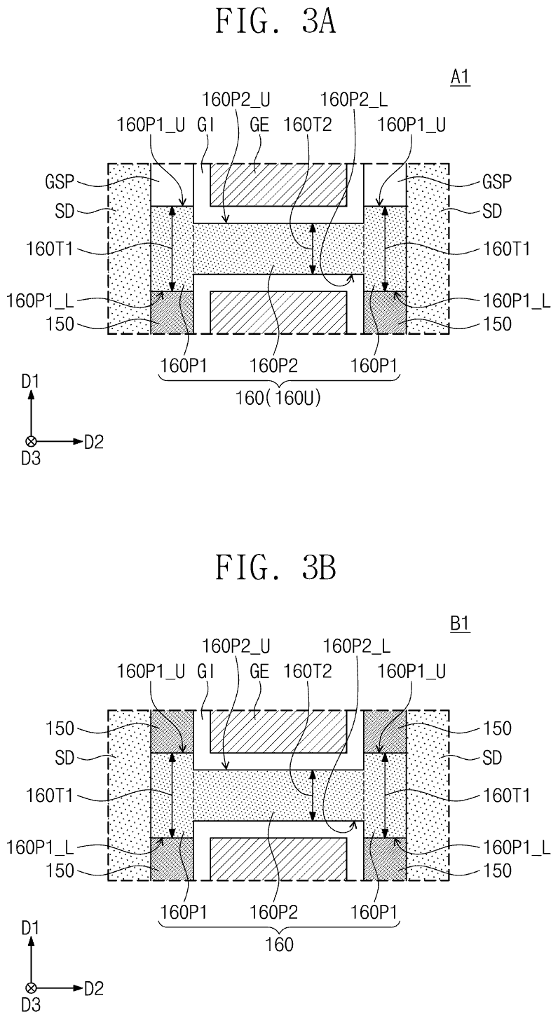

FIGS. 3A and 3B are enlarged sectional views illustrating portions A1 and B1 of FIG. 2, respectively.

Referring to FIGS. 1 and 2, a base active pattern 102 may be provided on a substrate 100. The substrate 100 may be a semiconductor substrate. For example, the substrate 100 may be a silicon substrate or a silicon-on-insulator (SOI) substrate. The base active pattern 102 may protrude from the substrate 100 in a first direction D1 that is perpendicular to a bottom surface 100L of the substrate 100 and may be lengthily extended in a second direction D2 that is parallel to the bottom surface 100L of the substrate 100. A plurality of the base active patterns 102 may be provided, and in this case, the base active patterns 102 may be arranged in a third direction D3 that is parallel to the bottom surface 100L of the substrate 100 but is not parallel to the second direction D2. In an embodiment, the base active pattern 102 may be formed of or may include silicon.

Device isolation patterns ST may be provided on portions of the substrate 100, which are located at opposite sides of the base active pattern 102. The device isolation patterns ST may be extended in the second direction D2 and may be spaced apart from each other, in the third direction D3, with the base active pattern 102 interposed therebetween. The device isolation patterns ST may be formed of or may include at least one of oxide, nitride, and/or oxynitride.

An active structure AS may be provided on the base active pattern 102. The active structure AS may be provided to be overlapped with the base active pattern 102, when viewed in a plan view. The active structure AS may be extended along a top surface of the base active pattern 102 or in the second direction D2. The active structure AS may include a channel pattern CH and source/drain patterns SD, which are spaced apart from each other in the second direction D2 with the channel pattern CH interposed therebetween. The channel pattern CH and the source/drain patterns SD may be arranged along the top surface of the base active pattern 102 or in the second direction D2. The active structures AS may be provided on the base active patterns 102, respectively. The plurality of active structures AS may be spaced apart from each other in the third direction D3.

The channel pattern CH may include a plurality of semiconductor patterns 160, which are stacked in the first direction D1. The semiconductor patterns 160 may be spaced apart from each other in the first direction D1. The lowermost one of the semiconductor patterns 160 may be an upper portion of the base active pattern 102. The semiconductor patterns 160 may be interposed between the source/drain patterns SD. Each of the semiconductor patterns 160 may be connected to the source/drain patterns SD and may be in direct contact with the source/drain patterns SD. Each of the source/drain patterns SD may be in contact with side surfaces of the semiconductor patterns 160. The number of the semiconductor patterns 160 is illustrated to be four, but the inventive concept is not limited to this example. The semiconductor patterns 160 may be formed of or may include the same semiconductor material as each other. Each of the semiconductor patterns 160 may be formed of or may include germanium (Ge) and, in an embodiment, it may be formed of or may include a silicon germanium (SiGe) alloy. It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element, there are no intervening elements present. Other words used to describe the relationship between elements should be interpreted in a like fashion (e.g., “between” versus “directly between,” “adjacent” versus “directly adjacent,” etc.).

The source/drain patterns SD may be epitaxial patterns, which are formed using the base active pattern 102 as a seed layer. The source/drain patterns SD may be formed of or may include at least one of silicon germanium (SiGe), silicon (Si), and silicon carbide (SiC). The source/drain patterns SD may be configured to exert a tensile strain or a compressive strain on the channel pattern CH. The source/drain patterns SD may further contain impurities. The impurities in the source/drain patterns SD may be used to improve electric characteristics of a transistor including the source/drain patterns SD. In the case where the transistor is an NMOSFET, the impurity may for example be phosphorus (P). In the case where the transistor is a PMOSFET, the impurity may for example be boron (B).

A gate structure GS may be provided on the active structure AS to cross the active structure AS. The gate structure GS may be extended in the third direction D3 to cross the active structure AS, the base active pattern 102 and the device isolation patterns ST. When viewed in a plan view, the channel pattern CH may be overlapped with the gate structure GS, and the source/drain patterns SD may be provided at opposite sides of the gate structure GS. The gate structure GS may be extended in the third direction D3 to cross the plurality of active structures AS.

The gate structure GS may include a gate electrode GE on the channel pattern CH, a gate insulating pattern GI between the gate electrode GE and the channel pattern CH, gate spacers GSP on side surfaces of the gate electrode GE, and a gate capping pattern CAP on a top surface of the gate electrode GE.

The gate electrode GE may be disposed on the uppermost one of the semiconductor patterns 160 of the channel pattern CH and may be extended into regions between the semiconductor patterns 160. In some embodiments, the gate electrode GE may surround each of the semiconductor patterns 160, except for the lowermost semiconductor pattern 160L. In some embodiment, a portion of the gate electrode GE, except for the uppermost portion of the gate electrode GE, may be disposed between two adjacent semiconductor patterns. The uppermost portion of gate electrode GE may be thicker than the other portions of the gate electrode GE. The gate electrode GE may be extended in the third direction D3 and may cover side surfaces of the channel pattern CH (or of each of the semiconductor patterns 160), which are opposite to each other in the third direction D3, and top surfaces of the device isolation patterns ST.

The gate spacers GSP may be disposed on the uppermost semiconductor pattern 160 and may be extended along the side surfaces of the gate electrode GE to cover the side surfaces of the gate electrode GE. In some embodiment, the gate spacers GS may be disposed on sidewalls of the uppermost portion of the gate electrode GE. The gate insulating pattern GI may be interposed between the gate electrode GE and the uppermost semiconductor pattern 160 and may be extended into regions between the gate electrode GE and the gate spacers GSP. The topmost surface of the gate insulating pattern GI may be substantially coplanar with the top surface of the gate electrode GE. The gate insulating pattern GI may be interposed between each of the semiconductor patterns 160 and the gate electrode GE and may enclose an outer surface of each of the semiconductor patterns 160. Each of the semiconductor patterns 160 may be spaced apart from the gate electrode GE with the gate insulating pattern GI interposed therebetween. The gate insulating pattern GI may be extended into a region between each of the source/drain patterns SD and the gate electrode GE. The gate insulating pattern GI may be extended along a bottom surface of the gate electrode GE and may be interposed between the gate electrode GE and each of the device isolation patterns ST. The gate capping pattern CAP may be extended along the top surface of the gate electrode GE or in the third direction D3. The gate spacers GSP may be extended to side surfaces of the gate capping pattern CAP, and the topmost surfaces of the gate spacers GSP may be substantially coplanar with a top surface of the gate capping pattern CAP. The gate electrode GE, the channel pattern CH, and the source/drain patterns SD may constitute a gate-all-around-type field effect transistor or a multi-bridge channel field effect transistor (MBCFET). Terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

The gate electrode GE may be formed of or may include at least one of doped semiconductor materials, conductive metal nitrides, and metallic materials. The gate insulating pattern GI may be formed of or may include at least one of silicon oxide, silicon nitride, silicon oxynitride, and a high-k dielectric material. The high-k dielectric material may include materials (e.g., hafnium oxide (HfO), aluminum oxide (AlO), or tantalum oxide (TaO)) having a higher dielectric constant than silicon oxide. Each of the gate spacers GSP and the gate capping pattern CAP may be formed of or may include at least one of silicon oxide, silicon nitride, and silicon oxynitride.

Spacer patterns 150 may be interposed between the semiconductor patterns 160 of the channel pattern CH and may be spaced apart from each other with the gate electrode GE interposed therebetween. In some embodiments, each pair of the spacer patterns 150 may be disposed on opposite sidewalls of a corresponding portion of the gate electrode GE which is lower than the uppermost portion of the gate electrode GE. Each of the spacer patterns 150 may be interposed between a corresponding one of the source/drain patterns SD and the gate electrode GE. Each of the source/drain patterns SD may be in contact with the semiconductor patterns 160 and may be spaced apart from the gate electrode GE with the spacer patterns 150 interposed therebetween. Each of the source/drain patterns SD may be in contact with corresponding ones of the spacer patterns 150. The gate insulating pattern GI may be interposed between the gate electrode GE and each of the semiconductor patterns 160 and may be extended into a region between the gate electrode GE and each of the spacer patterns 150. Each of the spacer patterns 150 may be in contact with the gate insulating pattern GI. The spacer patterns 150 may include or may be formed of a low-k dielectric layer. In an embodiment, the spacer patterns 150 may be formed of or may include at least one of SiN, SiCN, SiOCN, SiBCN, and SiBN. In some embodiment, the gate spacer GSP may be formed of a material different from a material of the spacer patterns 150. The present invention is not limited thereto. For example, the gate spacer GSP and the spacer patterns 150 may be formed of the same material as each other such as SiN.

Referring to FIGS. 2, 3A, and 3B, each of the semiconductor patterns 160 of the channel pattern CH may include first portions 160P1, which are overlapped with the gate spacers GSP vertically (e.g., in the first direction D1), and a second portion 160P2 between the first portions 160P1. The first portions 160P1 may be edge portions of each of the semiconductor patterns 160, and the second portion 160P2 may be an intermediate portion of each of the semiconductor patterns 160. The first portions 160P1 of each of the semiconductor patterns 160 may be overlapped with the spacer patterns 150 vertically (e.g., in the first direction D1), and the second portion 160P2 of each of the semiconductor patterns 160 may be overlapped with the gate electrode GE vertically (e.g., in the first direction D1). The first portions 160P1 of each of the semiconductor patterns 160 may include germanium (e.g., a silicon germanium (SiGe) alloy), and the second portion 160P2 of each of the semiconductor patterns 160 may also include germanium (e.g., a silicon germanium (SiGe) alloy). Each of the semiconductor patterns 160 may be formed of a single material (e.g., a silicon germanium (SiGe) alloy).

Each of the semiconductor patterns 160 may have a thickness in the first direction D1. In some embodiments, a thickness 160T1 of the first portions 160P1 of the uppermost semiconductor pattern 160U of the semiconductor patterns 160 may be larger than a thickness 160T2 of the second portion 160P2 of the uppermost semiconductor pattern 160U. Top surfaces 160P1_U of the first portions 160P1 of the uppermost semiconductor pattern 160U may be located at a height that is higher than a top surface 160P2_U of the second portion 160P2 of the uppermost semiconductor pattern 160U, when measured from the substrate 100. In the present specification, the height may be a distance measured from the bottom surface 100L of the substrate 100. Bottom surfaces 160P1_L of the first portions 160P1 of the uppermost semiconductor pattern 160U may be located at a height that is lower than a bottom surface 160P2_L of the second portion 160P2 of the uppermost semiconductor pattern 160U, when measured from the substrate 100. In some embodiments, the thickness 160T1 of the first portions 160P1 of each of the semiconductor patterns 160 may be larger than the thickness 160T2 of the second portion 160P2 of each of the semiconductor patterns 160. The top surfaces 160P1_U of the first portions 160P1 of each of the semiconductor patterns 160 may be located at a height that is higher than the top surface 160P2_U of the second portion 160P2 of each of the semiconductor patterns 160, when measured from the substrate 100. The bottom surfaces 160P1_L of the first portions 160P1 of each of the remaining ones of the semiconductor patterns 160, except the lowermost semiconductor pattern 160L, may be located at a height that is lower than the bottom surface 160P2_L of the second portion 160P2 of each of the remaining semiconductor patterns 160, when measured from the substrate 100. For example, each of the semiconductor patterns 160 may have a recessed top surface, and each of the semiconductor patterns 160, except for the lowermost semiconductor pattern 160L, may have a recessed bottom surface.

The top surfaces 160P1_U of the first portions 160P1 of the uppermost semiconductor pattern 160U of the semiconductor patterns 160 may be in contact with the gate spacers GSP, and the top surface 160P2_U of the second portion 160P2 of the uppermost semiconductor pattern 160U may be in contact with the gate insulating pattern GI. The bottom surfaces 160P1_L of the first portions 160P1 of the uppermost semiconductor pattern 160U may be in contact with corresponding ones of the spacer patterns 150, and the bottom surface 160P2_L of the second portion 160P2 of the uppermost semiconductor pattern 160U may be in contact with the gate insulating pattern GI. The top surfaces 160P1_U of the first portions 160P1 of the lowermost semiconductor pattern 160L of the semiconductor patterns 160 may be in contact with corresponding ones of the spacer patterns 150, and the top surface 160P2_U of the second portion 160P2 of the lowermost semiconductor pattern 160L may be in contact with the gate insulating pattern GI. The bottom surfaces 160P1_L of the first portions 160P1 and the bottom surface 160P2_L of the second portion 160P2 of the lowermost semiconductor pattern 160L may be in contact with the base active pattern 102. In each of the remaining ones of the semiconductor patterns 160, except the uppermost and lowermost semiconductor patterns 160U and 160L, the top and bottom surfaces 160P1_U and 160P1_L of the first portions 160P1 may be in contact with corresponding ones of the spacer patterns 150, and the top and bottom surfaces 160P2_U and 160P2_L of the second portion 160P2 may be in contact with the gate insulating pattern GI.

Referring back to FIGS. 1 and 2, a first interlayer insulating layer may be provided on the substrate 100 to cover the gate structure GS and the source/drain patterns SD. The first interlayer insulating layer may include or may be formed of at least one of a silicon oxide layer, a silicon nitride layer, a silicon oxynitride layer, and a low-k dielectric layer. The top surface of the gate capping pattern CAP may be substantially coplanar with a top surface of the first interlayer insulating layer. A second interlayer insulating layer 190 may be disposed on the first interlayer insulating layer to cover the top surface of the gate capping pattern CAP. The second interlayer insulating layer 190 may include or may be formed of at least one of a silicon oxide layer, a silicon nitride layer, a silicon oxynitride layer, and a low-k dielectric layer. First contact plugs CT may be disposed at opposite sides of the gate structure GS. Each of the first contact plugs CT may be provided to penetrate the second interlayer insulating layer 190 and the first interlayer insulating layer and may be electrically connected to a corresponding one of the source/drain patterns SD. Although not shown, a second contact plug may be disposed in the second interlayer insulating layer 190 and may be electrically connected to the gate electrode GE through the second interlayer insulating layer 190. Interconnection lines (not shown), which are coupled to the first contact plugs CT and the second contact plug, may be disposed on the second interlayer insulating layer. The interconnection lines may be used to apply voltages to the source/drain patterns SD and the gate electrode GE through the first contact plugs CT and the second contact plug. The first contact plugs CT, the second contact plug, and the interconnection lines may be formed of or may include at least one of conductive materials.

According to an embodiment of the inventive concept, each of the semiconductor patterns 160 of the channel pattern CH may be formed of a single material (e.g., a silicon germanium (SiGe) alloy). Accordingly, it may be possible to improve a carrier mobility property of a transistor including the channel pattern CH. At least a portion of each of the semiconductor patterns 160 may have a relatively thin thickness. Thus, it may be possible to easily reduce a size of the transistor and thereby to easily increase an integration density of the semiconductor device including the transistor.

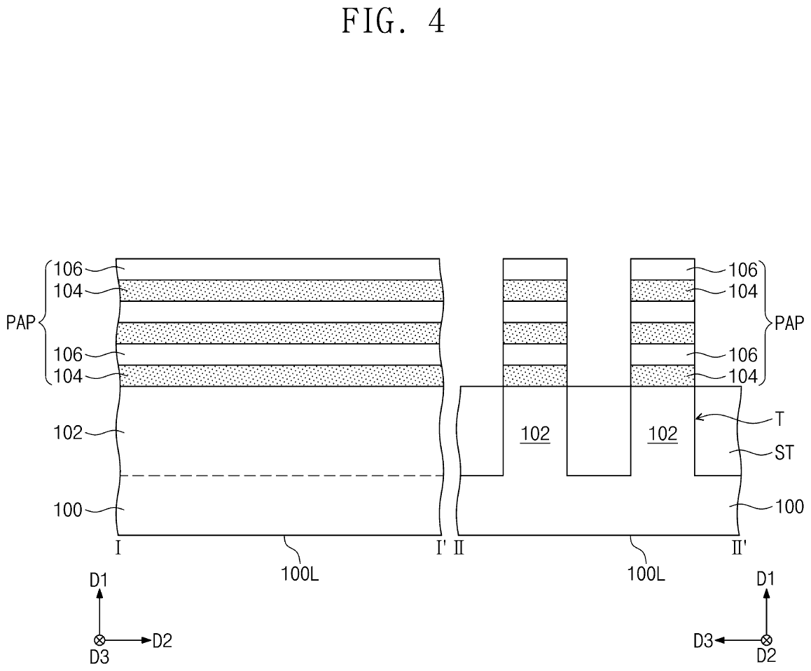

FIGS. 4 to 10 are sectional views, which correspond to the lines I-I′ and II-II′ of FIG. 1 and illustrate a method of fabricating a semiconductor device, according to some embodiments of the inventive concept. For concise description, an element previously described with reference to FIGS. 1, 2, 3A, and 3B may be identified by the same reference number without repeating an overlapping description thereof.

Referring to FIGS. 1 and 4, sacrificial layers 104 and semiconductor layers 106 may be alternately and repeatedly stacked on a substrate 100. The sacrificial layers 104 and the semiconductor layers 106 are illustrated to have a triple-layered structure, but the inventive concept is not limited to this example. Each of the sacrificial layers 104 and the semiconductor layers 106 may have a thickness in a direction (e.g., the first direction D1) that is perpendicular to the bottom surface 100L of the substrate 100. A thickness of each of the sacrificial layers 104 may have a value between about 1 Å and about 100 nm, and a thickness of each of the semiconductor layers 106 may have a value between about 1 Å and about 100 nm. The sacrificial layers 104 may be formed of or may include a material that has etch selectivity with respect to the semiconductor layers 106. As an example, the sacrificial layers 104 may be silicon germanium (SiGe) layers, and the semiconductor layers 106 may be silicon (Si) layers. The sacrificial layers 104 and the semiconductor layers 106 may be formed by performing an epitaxial growth process, in which the substrate 100 is used as a seed layer. The sacrificial layers 104 and the semiconductor layers 106 may be formed to have the same thickness or to have different thicknesses from each other. Terms such as “about” or “approximately” may reflect amounts, sizes, orientations, or layouts that vary only in a small relative manner, and/or in a way that does not significantly alter the operation, functionality, or structure of certain elements. For example, a range “from about 0.1 to about 1” or a range “between about 0.1 and about 1” may encompass a range such as a 0%-5% deviation around 0.1 and a 0% to 5% deviation around 1, especially if such deviation maintains the same effect as the listed range.

A preliminary active pattern PAP may be formed on the substrate 100, and a base active pattern 102 may be formed in the substrate 100. The formation of the preliminary active pattern PAP and the base active pattern 102 may include sequentially patterning the sacrificial layers 104, the semiconductor layers 106, and an upper portion of the substrate 100 to form trenches T defining the preliminary active pattern PAP and the base active pattern 102. The trenches T may be line-shaped regions extending in the second direction D2 and may be spaced apart from each other in the third direction D3. The preliminary active pattern PAP may be formed by patterning the sacrificial layers 104 and the semiconductor layers 106. The preliminary active pattern PAP may be a line-shaped pattern extending in the second direction D2. The base active pattern 102 may be formed by patterning the upper portion of the substrate 100. The base active pattern 102 may be a line-shaped pattern extending in the second direction D2, and the preliminary active pattern PAP may be formed on the top surface of the base active pattern 102.

Device isolation patterns ST may be formed to fill the trenches T, respectively. The device isolation patterns ST may be formed on the substrate 100 and at opposite sides of the base active pattern 102. The device isolation patterns ST may be extended in the second direction D2 and may be spaced apart from each other in the third direction D3 with the base active pattern 102 interposed therebetween. The formation of the device isolation patterns ST may include forming an insulating layer on the substrate 100 to fill the trenches T and recessing the insulating layer to completely expose side surfaces of the preliminary active pattern PAP. The device isolation patterns ST may be formed of or may include at least one of oxide, nitride, and oxynitride.

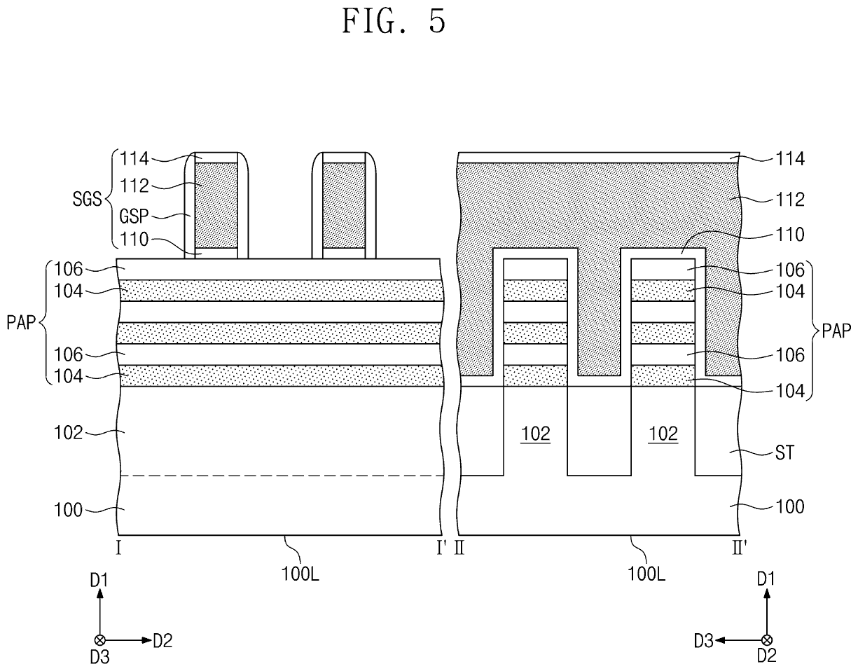

Referring to FIGS. 1 and 5, sacrificial gate structure SGS may be formed to cross the preliminary active pattern PAP. The sacrificial gate structure SGS may be extended in the third direction D3 to cross the preliminary active pattern PAP, the base active pattern 102, and the device isolation patterns ST. The sacrificial gate structure SGS may include an etch stop pattern 110, a sacrificial gate pattern 112, and a mask pattern 114, which are sequentially stacked on the substrate 100. The sacrificial gate pattern 112 may be a line-shaped pattern extending in the third direction D3. The sacrificial gate pattern 112 may cover side surfaces of the preliminary active pattern PAP, which are opposite to each other in the third direction D3, a top surface of the preliminary active pattern PAP, and top surfaces of the device isolation patterns ST. The etch stop pattern 110 may be interposed between the sacrificial gate pattern 112 and the preliminary active pattern PAP and may be extended into a region between the sacrificial gate pattern 112 and each of the device isolation patterns ST. The formation of the sacrificial gate pattern 112 and the etch stop pattern 110 may include sequentially forming an etch stop layer (not shown) and a sacrificial gate layer (not shown) on the substrate 100 to cover the preliminary active pattern PAP and the device isolation patterns ST, forming the mask pattern 114 on the sacrificial gate layer to define a region, on which the sacrificial gate pattern 112 will be formed, and sequentially patterning the sacrificial gate layer and the etch stop layer using the mask pattern 114 as an etch mask. In an embodiment, the etch stop layer may include or may be formed of a silicon oxide layer. The sacrificial gate layer may include or may be formed of a material that has etch selectivity with respect to the etch stop layer. The sacrificial gate layer may be formed of or may include, for example, poly silicon. The sacrificial gate pattern 112 may be formed by patterning the sacrificial gate layer using the mask pattern 114 as an etch mask. The patterning of the sacrificial gate layer may include performing an etching process having etch selectivity with respect to the etch stop layer. After the formation of the sacrificial gate pattern 112, the etch stop layer may be removed at opposite sides of the sacrificial gate pattern 112, and thus, the etch stop pattern 110 may be locally formed below the sacrificial gate pattern 112.

The sacrificial gate structure SGS may further include gate spacers GSP, which are formed at opposite sides of the sacrificial gate pattern 112. The formation of the gate spacers GSP may include forming a gate spacer layer (not shown) on the substrate 100 to cover the mask pattern 114, the sacrificial gate pattern 112, and the etch stop pattern 110, and anisotropically etching the gate spacer layer. The mask pattern 114 and the gate spacers GSP may be formed of or may include, for example, silicon nitride.

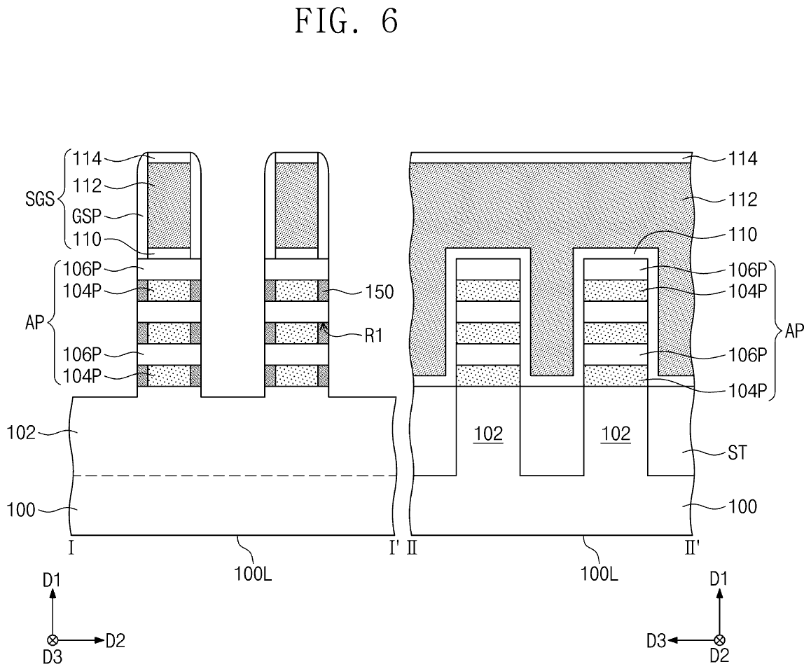

Referring to FIGS. 1 and 6, an active pattern AP may be formed below the sacrificial gate structure SGS by patterning the preliminary active pattern PAP. The formation of the active pattern AP may include removing portions of the preliminary active pattern PAP, which are located at opposite sides of the sacrificial gate structure SGS. The removing of the portions of the preliminary active pattern PAP may include etching the portions of the preliminary active pattern PAP using the mask pattern 114 and the gate spacers GSP as an etch mask. The etching of the portions of the preliminary active pattern PAP may be performed until the top surface of the base active pattern 102 is exposed at opposite sides of the sacrificial gate structure SGS. In some embodiments, the etching of the portions of the preliminary active pattern PAP may further include recessing the top surface of the base active pattern 102 at opposite sides of the sacrificial gate structure SGS.

The active pattern AP may include sacrificial patterns 104P and preliminary semiconductor patterns 106P, which are alternately and repeatedly stacked on the base active pattern 102. The sacrificial patterns 104P may be formed by patterning the sacrificial layers 104, and the preliminary semiconductor patterns 106P may be formed by patterning the semiconductor layers 106. Since the portions of the preliminary active pattern PAP are etched, side surfaces of the sacrificial patterns 104P and side surfaces of the preliminary semiconductor patterns 106P may be exposed at opposite sides of the sacrificial gate structure SGS.

The exposed side surfaces of the sacrificial patterns 104P may be horizontally recessed, and in this case, recess regions R1 may be formed to expose opposite side surfaces of each of the sacrificial patterns 104P. Each of the recess regions R1 may be formed between adjacent ones of the preliminary semiconductor patterns 106P or between the lowermost one of the preliminary semiconductor patterns 106P and the base active pattern 102. Each of the recess regions R1 may expose a side surface of a corresponding one of the sacrificial patterns 104P.

Spacer patterns 150 may be formed in the recess regions R1, respectively. The formation of the spacer patterns 150 may include conformally forming a spacer layer on the substrate 100 to fill the recess regions R1 and anisotropically etching the spacer layer to locally form the spacer patterns 150 in the recess regions R1.

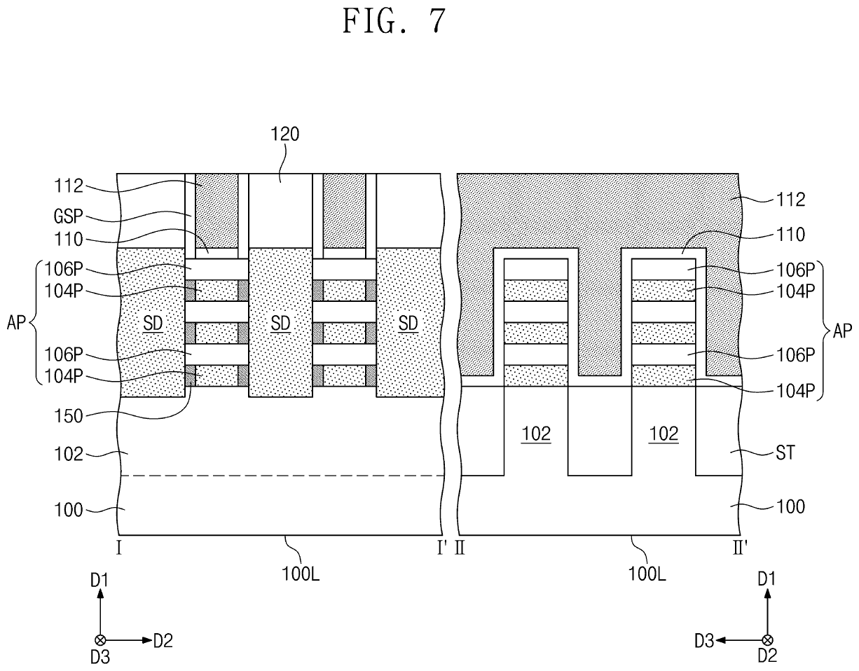

Referring to FIGS. 1 and 7, source/drain patterns SD may be formed on the base active pattern 102 and at opposite sides of the sacrificial gate structure SGS. The source/drain patterns SD may be formed by a selective epitaxial growth process, in which the preliminary semiconductor patterns 106P and the base active pattern 102 are used as a seed layer. Each of the source/drain patterns SD may be in contact with the exposed side surfaces of the preliminary semiconductor patterns 106P and may be in contact with the top surface of the base active pattern 102. The source/drain patterns SD may be spaced apart from each of the sacrificial patterns 104P with the spacer patterns 150 interposed therebetween. The source/drain patterns SD may be in contact with the spacer patterns 150.

The source/drain patterns SD may be formed of or may include at least one of silicon-germanium (SiGe), silicon (Si), and silicon carbide (SiC). The formation of the source/drain patterns SD may further include doping the source/drain patterns SD with an impurity during or after the selective epitaxial growth process. The impurity doping process may be performed to improve electric characteristics of the transistor including the source/drain patterns SD. In the case where the transistor is an NMOSFET, the impurity may be, for example, phosphorus (P), and in the case where the transistor is a PMOSFET, the impurity may be, for example, boron (B).

A first interlayer insulating layer 120 may be formed on the substrate 100 provided with the source/drain patterns SD. The formation of the first interlayer insulating layer 120 may include forming an insulating layer on the substrate 100 to cover the source/drain patterns SD and the sacrificial gate structure SGS and planarizing the insulating layer to expose the sacrificial gate pattern 112. The mask pattern 114 may be removed, as a result of the planarization process. The first interlayer insulating layer 120 may include or may be formed of at least one of a silicon oxide layer, a silicon nitride layer, a silicon oxynitride layer, and a low-k dielectric layer.

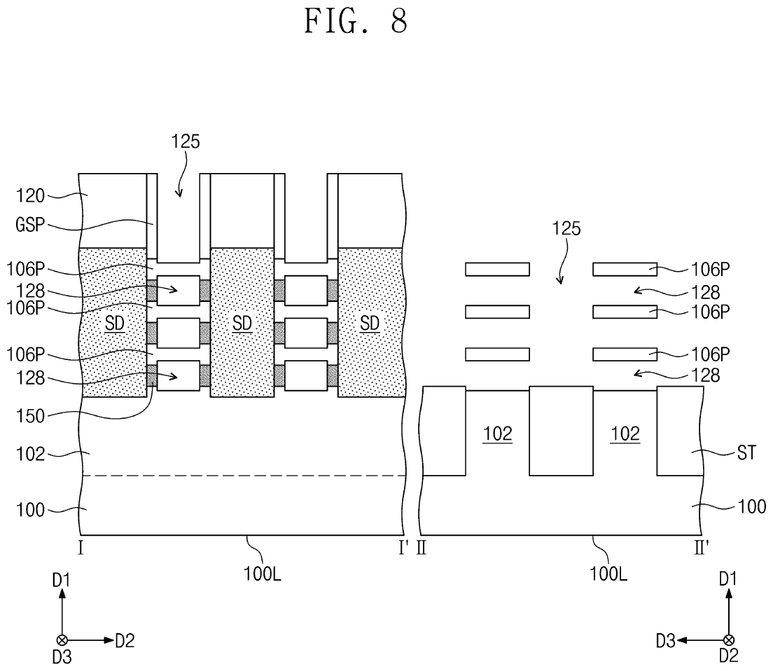

Referring to FIGS. 1 and 8, the sacrificial gate pattern 112 and the etch stop pattern 110 may be removed to form a gap region 125 in the first interlayer insulating layer 120. The gap region 125 may be an empty region that is defined by the gate spacers GSP. The gap region 125 may expose the active pattern AP. The formation of the gap region 125 may include etching the sacrificial gate pattern 112 using an etch recipe, which has etch selectivity with respect to the gate spacer GSP, the first interlayer insulating layer 120, and the etch stop pattern 110, and removing the etch stop pattern 110 to expose the preliminary semiconductor patterns 106P and the sacrificial patterns 104P. The gap region 125 may be a line-shaped region extending in the third direction D3, when viewed in a plan view, and may expose the top surfaces of the device isolation patterns ST.

The exposed sacrificial patterns 104P may be selectively removed. In the case where the sacrificial patterns 104P include or are formed of silicon-germanium (SiGe) and the preliminary semiconductor patterns 106P include or are formed of silicon (Si), the sacrificial patterns 104P may be selectively removed by a wet etching process using peracetic acid as an etchant. During the selective removal process, the source/drain patterns SD may be protected by the first interlayer insulating layer 120 and the spacer patterns 150. As a result of the selective removal of the sacrificial patterns 104P, empty regions 128 (i.e., spaces) may be formed between the preliminary semiconductor patterns 106P and between the lowermost one of the preliminary semiconductor patterns 106P and the base active pattern 102. The empty regions 128 may be connected to the gap region 125 and thus the empty regions 128 and the gap region 125 may be connected to each other.

The gap region 125 and the empty regions 128 may be formed to expose not only top and bottom surfaces of the preliminary semiconductor patterns 106P but also the top surface of the base active pattern 102. In some embodiments, the exposed top and bottom surfaces of the preliminary semiconductor patterns 106P and the exposed top surface of the base active pattern 102 may be recessed by a trimming process. Each of the preliminary semiconductor patterns 106P may include first portions, which are overlapped with the gate spacers GSP and the spacer patterns 150 vertically (e.g., in the first direction D1), and a second portion, which is overlapped with the gap region 125 and the empty regions 128 vertically (e.g., in the first direction D1). Since the exposed top and bottom surfaces of the preliminary semiconductor patterns 106P are recessed by the trimming process, a thickness of the second portion of each of the preliminary semiconductor patterns 106P in the first direction D1 may be smaller than a thickness of the first portions of each of the preliminary semiconductor patterns 106P in the first direction D1. The upper portion of the base active pattern 102 may also be partially recessed during the trimming process.

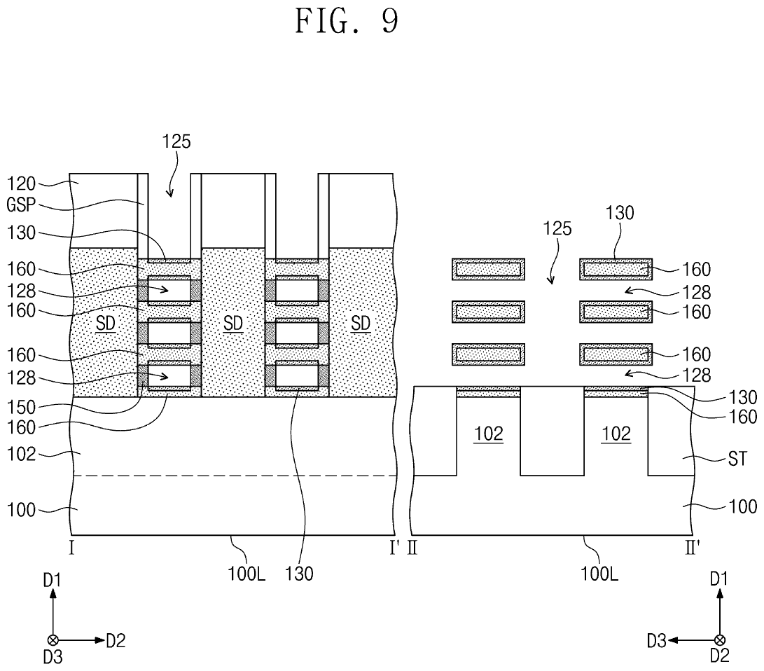

Referring to FIGS. 1 and 9, a germanium layer 130 may be formed on the preliminary semiconductor patterns 106P and the base active pattern 102 exposed by the gap region 125 and the empty regions 128. The germanium layer 130 may be formed by a selective growth process, in which the preliminary semiconductor patterns 106P and the base active pattern 102 are used as a seed layer, and may be formed on the recessed top and bottom surfaces of the preliminary semiconductor patterns 106P and the recessed top surface of the base active pattern 102.

A thermal treatment process may be performed after the formation of the germanium layer 130. As a result of the thermal treatment process, germanium (Ge) atoms in the germanium layer 130 may react with the preliminary semiconductor patterns 106P and an upper portion of the base active pattern 102. Accordingly, the preliminary semiconductor patterns 106P and the upper portion of the base active pattern 102 may be converted to semiconductor patterns 160. Each of the semiconductor patterns 160 may be formed of or may include a silicon germanium (SiGe) alloy. A germanium concentration in each of the semiconductor patterns 160 may be controlled by adjusting a process temperature and a process time in the thermal treatment process. As an example, in the case where the process temperature and/or time of the thermal treatment process are increased, the germanium concentration in each of the semiconductor patterns 160 may be increased.

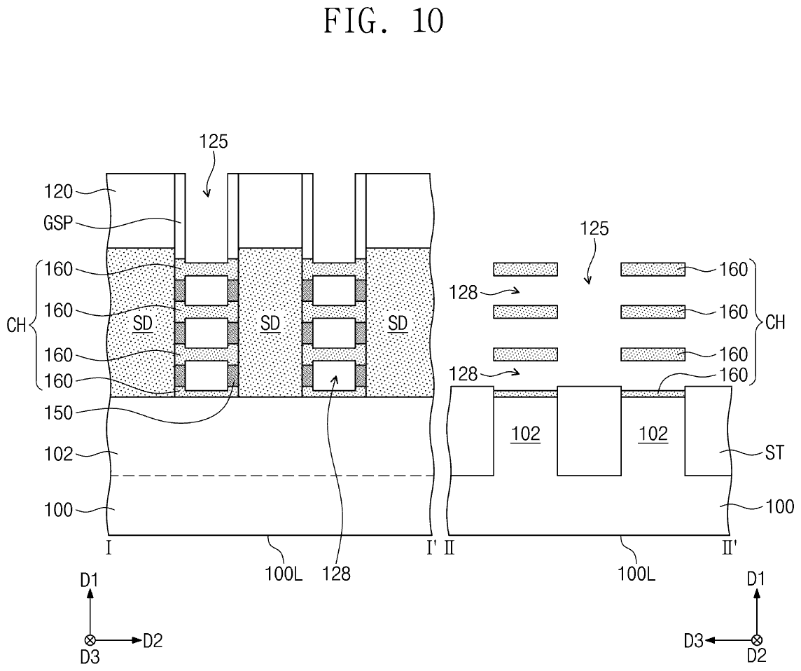

Referring to FIGS. 1 and 10, the germanium layer 130 may be removed after the formation of the semiconductor patterns 160. The germanium layer 130 may be removed by, for example, a strip process. For example, the germanium layer 130 that remains after the formation of the semiconductor patterns 160 may be removed using a strip process, for example. The semiconductor patterns 160 may be referred to as a channel pattern CH and may be connected to the source/drain patterns SD.

According to an embodiment of the inventive concept, the germanium layer 130 may be removed after the formation of the semiconductor patterns 160. Accordingly, each of the semiconductor patterns 160 may be formed to have a relatively thin thickness. A thickness of the semiconductor patterns 160 may be easily controlled by the trimming process of recessing the exposed top and bottom surfaces of the preliminary semiconductor patterns 106P.

Referring back to FIGS. 1 and 2, a gate insulating pattern GI and a gate electrode GE may be formed to fill the gap region 125 and the empty regions 128. The formation of the gate insulating pattern GI and the gate electrode GE may include forming a gate insulating layer to conformally cover inner surfaces of the gap region 125 and the empty regions 128, forming a gate conductive layer to fill remaining spaces of the gap region 125 and the empty regions 128, and performing a planarization process to expose the first interlayer insulating layer 120, and as a result, the gate insulating pattern GI and the gate electrode GE may be locally formed in the gap region 125 and the empty regions 128. The gate electrode GE may be spaced apart from the semiconductor patterns 160 with the gate insulating pattern GI interposed therebetween and may be spaced apart from the source/drain patterns SD with the spacer patterns 150 interposed therebetween.

A groove region may be formed between the gate spacers GSP by recessing upper portions of the gate insulating pattern GI and the gate electrode GE. A gate capping pattern CAP may be formed in the groove region. The formation of the gate capping pattern CAP may include forming a gate capping layer on the first interlayer insulating layer 120 to fill the groove region and planarizing the gate capping layer to expose the first interlayer insulating layer 120.

The gate insulating pattern GI, the gate electrode GE, the gate capping pattern CAP, and the gate spacers GSP may constitute a gate structure GS. The semiconductor patterns 160 may constitute the channel pattern CH. The source/drain patterns SD may be spaced apart from each other in the second direction D2 with the channel pattern CH interposed therebetween, and each of the source/drain patterns SD may be in contact with the channel pattern CH. The channel pattern CH and the source/drain patterns SD may constitute an active structure AS provided on the base active pattern 102. The active structure AS and the gate electrode GE may constitute a gate-all-around-type field effect transistor or a multi-bridge channel field effect transistor (MBCFET).

A second interlayer insulating layer 190 may be formed on the first interlayer insulating layer 120. First contact plugs CT may be formed to penetrate the second interlayer insulating layer 190 and the first interlayer insulating layer 120 and to be connected to the source/drain patterns

SD, and a second contact plug (not shown) may be formed to penetrate the second interlayer insulating layer 190 and to be connected to the gate electrode GE. Interconnection lines (not shown), which are electrically connected to the first contact plugs CT and the second contact plug, may be formed on the second interlayer insulating layer 190.

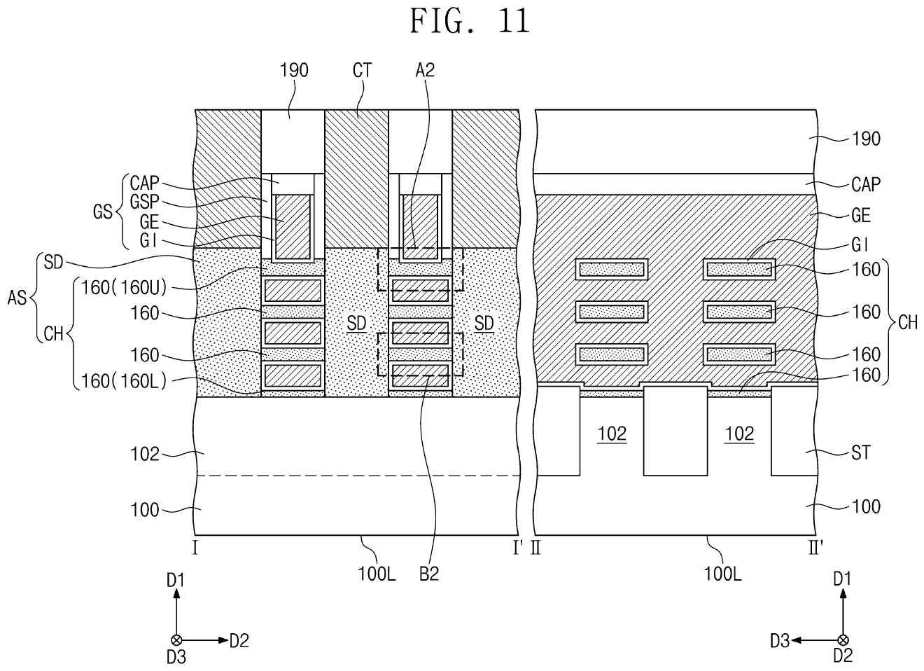

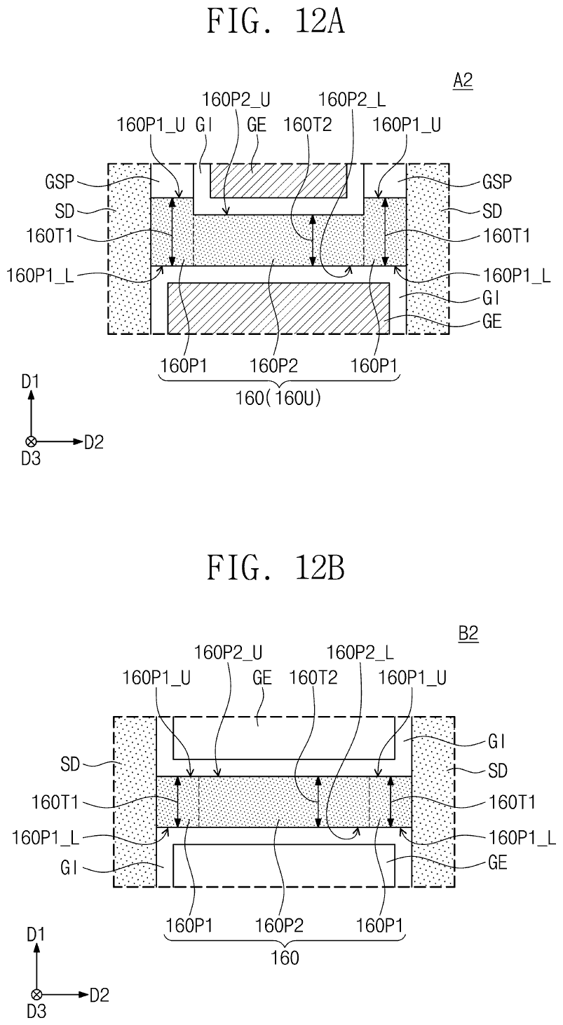

FIG. 11 is a sectional view, which corresponds to the lines I-I′ and II-II′ of FIG. 1 and illustrates a semiconductor device according to some embodiments of the inventive concept. FIGS. 12A and 12B are enlarged sectional views illustrating portions A2 and B2 of FIG. 11, respectively. For concise description, an element previously described with reference to FIGS. 1, 2, 3A, and 3B may be identified by the same reference number without repeating an overlapping description thereof.

Referring to FIGS. 11, 12A, and 12B, the spacer patterns 150 described with reference to FIGS. 1, 2, 3A, and 3B may be omitted from the semiconductor devices according to some embodiments of the inventive concept. The gate insulating pattern GI may be interposed between each of the source/drain patterns SD and the gate electrode GE, and each of the source/drain patterns SD may be in contact with the gate insulating pattern GI.

In some embodiments, each of the semiconductor patterns 160 of the channel pattern CH may include first portions 160P1, which are overlapped with the gate spacers GSP vertically (e.g., in the first direction D1), and a second portion 160P2, which is provided between the first portions 160P1. The first portions 160P1 may be edge portions of each of the semiconductor patterns 160, and the second portion 160P2 may be an intermediate portion of each of the semiconductor patterns 160. The second portion 160P2 of each of the semiconductor patterns 160 may be overlapped with the gate electrode GE vertically (e.g., in the first direction D1). The first portions 160P1 of each of the semiconductor patterns 160 may include germanium (e.g., a silicon germanium (SiGe) alloy), and the second portion 160P2 of each of the semiconductor patterns 160 may also include germanium (e.g., a silicon germanium (SiGe) alloy). Each of the semiconductor patterns 160 may be formed of a single material (e.g., a silicon germanium (SiGe) alloy). Each of the semiconductor patterns 160 may have a thickness in the first direction D1. In some embodiments, a thickness 160T1 of the first portions 160P1 of the uppermost semiconductor pattern 160U of the semiconductor patterns 160 may be larger than a thickness 160T2 of the second portion 160P2 of the uppermost semiconductor pattern 160U. The top surfaces 160P1_U of the first portions 160P1 of the uppermost semiconductor pattern 160U may be located at a height that is higher than the top surface 160P2_U of the second portion 160P2 of the uppermost semiconductor pattern 160U, when measured from the substrate 100. In some embodiments, the bottom surfaces 160P1_L of the first portions 160P1 of the uppermost semiconductor pattern 160U may be located at the same height as the bottom surface 160P2_L of the second portion 160P2 of the uppermost semiconductor pattern 160U, when measured from the substrate 100. In some embodiments, the thickness 160T1 of the first portions 160P1 of each of the remaining ones of the semiconductor patterns 160 may be equal to the thickness 160T2 of the second portion 160P2 of each of the remaining semiconductor patterns 160. The top surfaces 160P1_U of the first portions 160P1 of each of the remaining semiconductor patterns 160 may be positioned at the same height as the top surface 160P2_U of the second portion 160P2 of each of the remaining semiconductor patterns 160, when measured from the substrate 100, and the bottom surfaces 160P1_L of the first portions 160P1 of each of the remaining semiconductor patterns 160 may be positioned at the same height as the bottom surface 160P2_L of the second portion 160P2 of each of the remaining semiconductor patterns 160, when measured from the substrate 100.

The top surfaces 160P1_U of the first portions 160P1 of the uppermost semiconductor pattern 160U of the semiconductor patterns 160 may be in contact with the gate spacers GSP, and the top surface 160P2_U of the second portion 160P2 of the uppermost semiconductor pattern 160U may be in contact with the gate insulating pattern GI. The bottom surfaces 160P1_L of the first portions 160P1 and the bottom surface 160P2_L of the second portion 160P2 of the uppermost semiconductor pattern 160U may be in contact with the gate insulating pattern GI. In the lowermost semiconductor pattern 160L of the semiconductor patterns 160, the top surfaces 160P1_U of the first portions 160P1 and the top surface 160P2_U of the second portion 160P2 may be in contact with the gate insulating pattern GI. In the lowermost semiconductor pattern 160L, the bottom surfaces 160P1_L of the first portions 160P1 and the bottom surface 160P2_L of the second portion 160P2 may be in contact with the base active pattern 102. In each of the remaining semiconductor patterns 160 of the semiconductor patterns 160, the top and bottom surfaces 160P1_U and 160P1_L of the first portions 160P1 and the top and bottom surfaces 160P2_U and 160P2_L of the second portion 160P2 may be in contact with the gate insulating pattern GI.

Except for the afore-described differences, the semiconductor device according to the present embodiments may be substantially the same as the semiconductor device described with reference to FIGS. 1, 2, 3A, and 3B.

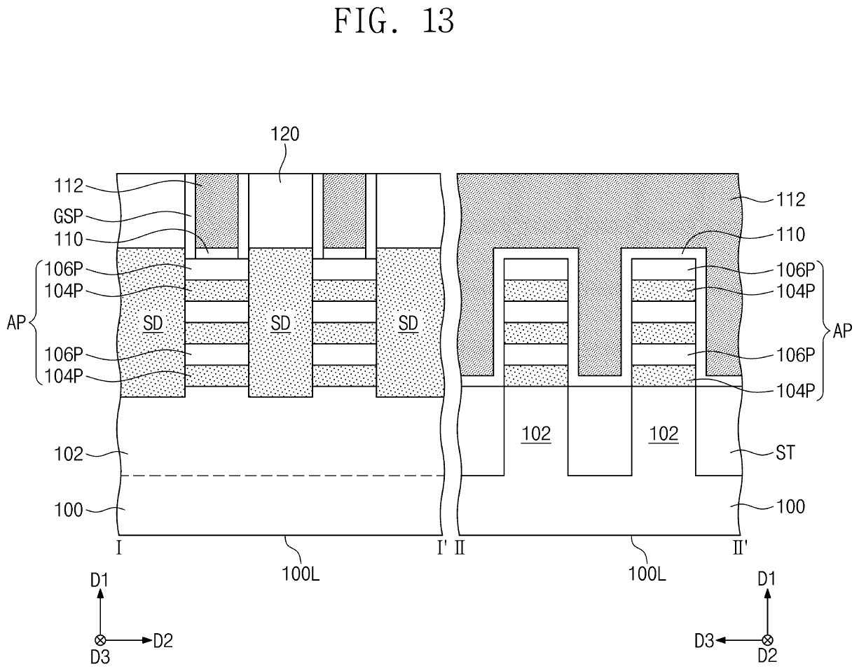

FIGS. 13 to 16 are sectional views, which correspond to the lines I-I′ and II-II′ of FIG. 1 and illustrate a method of fabricating a semiconductor device, according to some embodiments of the inventive concept. For concise description, an element or step previously described with reference to FIGS. 4 to 10 may be identified by the same reference number without repeating an overlapping description thereof.

As described with reference to FIGS. 1, 4, and 5, the sacrificial gate structure SGS may be formed to cross the preliminary active pattern PAP.

Referring to FIGS. 1 and 13, an active pattern AP may be formed below the sacrificial gate structure SGS by patterning the preliminary active pattern PAP (see, FIGS. 5 and 6). The formation of the active pattern AP may include removing portions of the preliminary active pattern PAP, which are located at opposite sides of the sacrificial gate structure SGS. The active pattern AP may include sacrificial patterns 104P and preliminary semiconductor patterns 106P, which are alternately and repeatedly stacked on the base active pattern 102. Since the portions of the preliminary active pattern PAP are etched, side surfaces of the sacrificial patterns 104P and side surfaces of the preliminary semiconductor patterns 106P may be exposed at opposite sides of the sacrificial gate structure SGS.

Source/drain patterns SD may be formed on the base active pattern 102 and at opposite sides of the sacrificial gate structure SGS. The source/drain patterns SD may be formed by a selective epitaxial growth process, in which the preliminary semiconductor patterns 106P and the base active pattern 102 are used as a seed layer. In some embodiments, each of the source/drain patterns SD may be in contact with the exposed side surfaces of the preliminary semiconductor patterns 106P and the exposed side surfaces of the sacrificial patterns 104P and may be in contact with the top surface of the base active pattern 102.

A first interlayer insulating layer 120 may be formed on the substrate 100 provided with the source/drain patterns SD. The formation of the first interlayer insulating layer 120 may include forming an insulating layer on the substrate 100 to cover the source/drain patterns SD and the sacrificial gate structure SGS and planarizing the insulating layer to expose the sacrificial gate pattern 112.

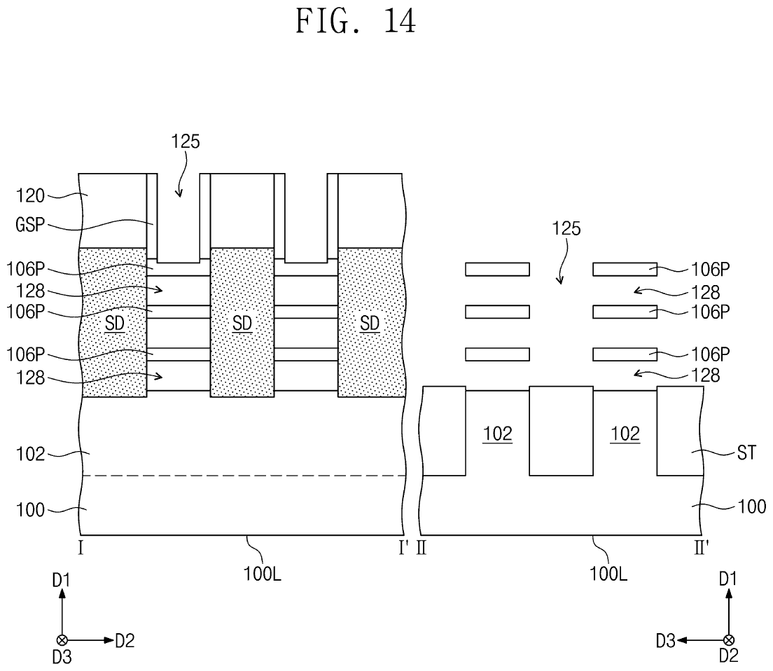

Referring to FIGS. 1 and 14, the sacrificial gate pattern 112 and the etch stop pattern 110 may be removed to form a gap region 125 in the first interlayer insulating layer 120. The sacrificial patterns 104P exposed by the gap region 125 may be selectively removed. Accordingly, empty regions 128 may be formed between the preliminary semiconductor patterns 106P and between the lowermost one of the preliminary semiconductor patterns 106P and the base active pattern 102. The empty regions 128 may be connected to the gap region 125 and thus the empty regions 128 and the gap region 125 may be connected to each other.

The gap region 125 and the empty regions 128 may be formed to expose not only top and bottom surfaces of the preliminary semiconductor patterns 106P but also the top surface of the base active pattern 102. In some embodiments, the exposed top and bottom surfaces of the preliminary semiconductor patterns 106P and the exposed top surface of the base active pattern 102 may be recessed by a trimming process. The uppermost one of the preliminary semiconductor patterns 106P may include first portions, which are overlapped with the gate spacers GSP vertically (e.g., in the first direction D1), and a second portion, which is provided between the first portions. As a result of the trimming process, a thickness of the second portion of the uppermost preliminary semiconductor pattern 106P in the first direction D1 may be smaller than a thickness of the first portions of the uppermost preliminary semiconductor pattern 106P in the first direction D1. A thickness of the remaining preliminary semiconductor patterns 106P of the preliminary semiconductor patterns 106P in the first direction D1 may be reduced by the trimming process. The upper portion of the base active pattern 102 may also be recessed by the trimming process.

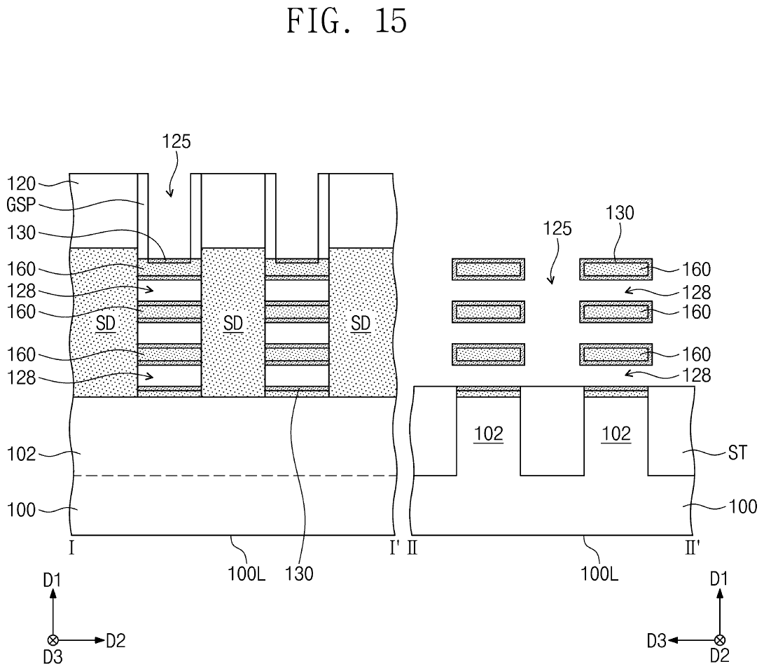

Referring to FIGS. 1 and 15, a germanium layer 130 may be formed on the preliminary semiconductor patterns 106P and the base active pattern 102 exposed by the gap region 125 and the empty regions 128. The germanium layer 130 may be formed on the recessed top and bottom surfaces of the preliminary semiconductor patterns 106P and the recessed top surface of the base active pattern 102. In some embodiments, the germanium layer 130 may be selectively formed on the recessed top and bottom surfaces of the preliminary semiconductor patterns 106P and the recessed top surface of the base active pattern 102.

A thermal treatment process may be performed after the formation of the germanium layer 130. As a result of the thermal treatment process, germanium (Ge) atoms in the germanium layer 130 may react with the preliminary semiconductor patterns 106P and an upper portion of the base active pattern 102. Accordingly, the preliminary semiconductor patterns 106P and the upper portion of the base active pattern 102 may be converted to semiconductor patterns 160. Each of the semiconductor patterns 160 may be formed of or may include a silicon germanium (SiGe) alloy.

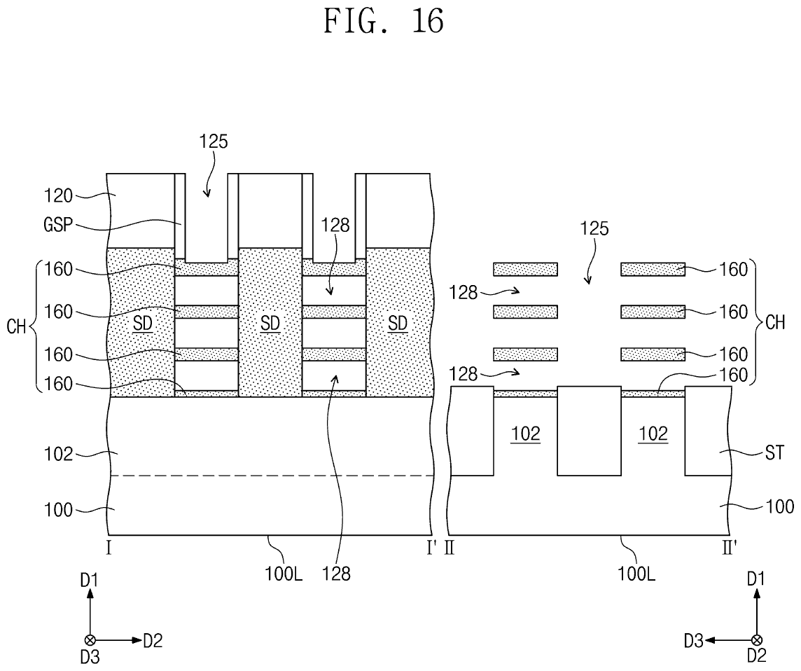

Referring to FIGS. 1 and 16, the germanium layer 130 may be removed after the formation of the semiconductor patterns 160. In some embodiment, the germanium layer 130 that remains after the formation of the semiconductor patterns 160 may be removed using a strip process, for example. The semiconductor patterns 160 may be referred to as a channel pattern CH and may be connected to the source/drain patterns SD.

Except for the afore-described difference, the method of fabricating a semiconductor device according to the present embodiment may be substantially the same as the method described with reference to FIGS. 1, 2, and 4 to 10.

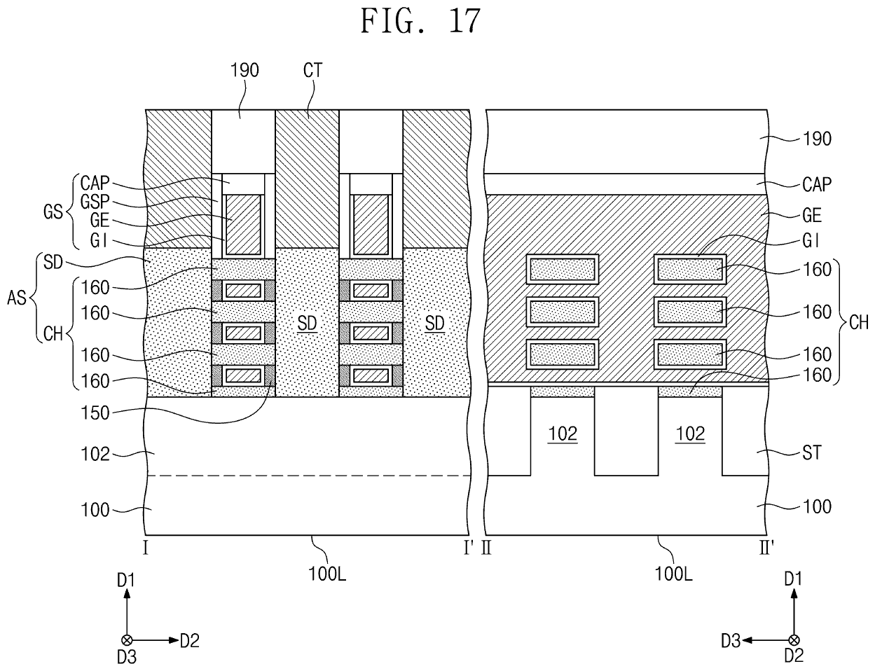

FIG. 17 is a sectional view, which corresponds to the lines I-I′ and II-II′ of FIG. 1 and illustrates a semiconductor device according to some embodiments of the inventive concept. For concise description, an element previously described with reference to FIGS. 1, 2, 3A, and 3B may be identified by the same reference number without repeating an overlapping description thereof.

Referring to FIG. 17, the semiconductor patterns 160 of the channel pattern CH may be formed of or may include the same semiconductor material as each other. Each of the semiconductor patterns 160 may include germanium (Ge). For example, each of the semiconductor patterns 160 may include or may be formed of a silicon germanium (SiGe) alloy. Each of the semiconductor patterns 160 may include first portions 160P1, which are overlapped with the gate spacers GSP vertically (e.g., in the first direction D1), and a second portion 160P2, which is provided between the first portions 160P1, as described with reference to FIGS. 3A and 3B. The first portions 160P1 of each of the semiconductor patterns 160 may be include germanium (e.g., a silicon germanium (SiGe) alloy), and the second portion 160P2 of each of the semiconductor patterns 160 may include germanium (e.g., a silicon germanium (SiGe) alloy). For example, each of the semiconductor patterns 160 may be formed of a single material (e.g., a silicon germanium (SiGe) alloy).

In some embodiments, unlike the structure shown in FIGS. 3A and 3B, the thickness 160T1 of the first portions 160P1 of each of the semiconductor patterns 160 may be equal to the thickness 160T2 of the second portion 160P2 of each of the semiconductor patterns 160. The top surfaces 160P1_U of the first portions 160P1 of each of the semiconductor patterns 160 may be located at the same height as the top surface 160P2_U of the second portion 160P2 of each of the semiconductor patterns 160, and the bottom surfaces 160P1_L of the first portions 160P1 of each of the semiconductor patterns 160 may be located at the same height as the bottom surface 160P2_L of the second portion 160P2 of each of the semiconductor patterns 160.

Except for the afore-described difference, the semiconductor device according to the present embodiments may be substantially the same as the semiconductor device described with reference to FIGS. 1, 2, 3A, and 3B.

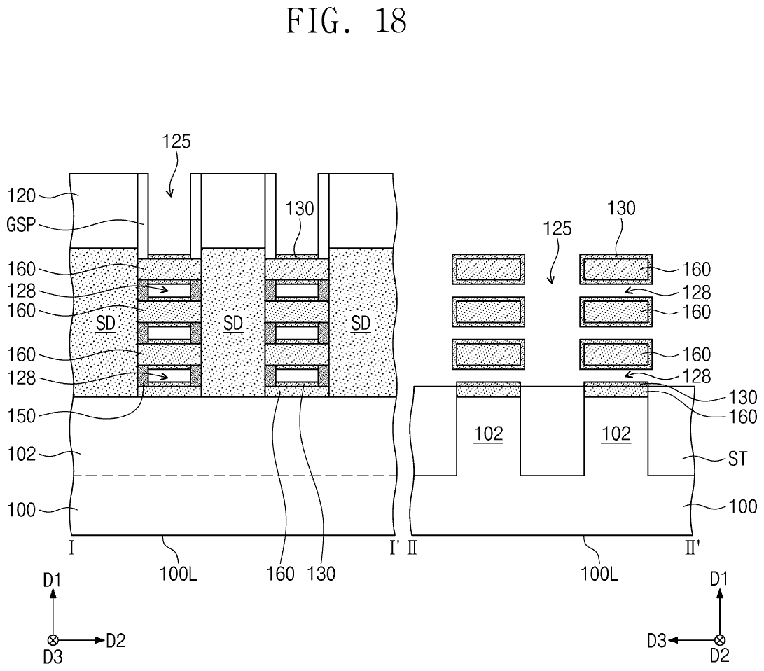

FIG. 18 is a sectional view, which corresponds to the lines I-I′ and II-II′ of FIG. 1 and illustrates a method of fabricating a semiconductor device, according to some embodiments of the inventive concept. For concise description, an element or step previously described with reference to FIGS. 4 to 10 may be identified by the same reference number without repeating an overlapping description thereof.

As described with reference to FIGS. 1 and 8, the sacrificial gate pattern 112 and the etch stop pattern 110 may be removed to form a gap region 125 in the first interlayer insulating layer 120. The sacrificial patterns 104P exposed by the gap region 125 may be selectively removed. Accordingly, empty regions 128 may be formed between the preliminary semiconductor patterns 106P and between the lowermost one of the preliminary semiconductor patterns 106P and the base active pattern 102. The empty regions 128 may be connected to the gap region 125 and thus the empty regions 128 and the gap region 125 may be connected to each other.

The gap region 125 and the empty regions 128 may be formed to expose not only top and bottom surfaces of the preliminary semiconductor patterns 106P but also the top surface of the base active pattern 102. In some embodiments, the trimming process of recessing the exposed top and bottom surfaces of the preliminary semiconductor patterns 106P and the exposed top surface of the base active pattern 102 may be omitted.

Referring to FIGS. 1 and 18, a germanium layer 130 may be formed on the preliminary semiconductor patterns 106P and the base active pattern 102 exposed by the gap region 125 and the empty regions 128. The germanium layer 130 may be formed on the exposed top and bottom surfaces of the preliminary semiconductor patterns 106P and the exposed top surface of the base active pattern 102.

A thermal treatment process may be performed after the formation of the germanium layer 130. As a result of the thermal treatment process, germanium (Ge) atoms in the germanium layer 130 may react with the preliminary semiconductor patterns 106P and an upper portion of the base active pattern 102. Accordingly, the preliminary semiconductor patterns 106P and the upper portion of the base active pattern 102 may be converted to semiconductor patterns 160. Each of the semiconductor patterns 160 may be formed of or may include a silicon germanium (SiGe) alloy.

Except for the afore-described difference, the method of fabricating a semiconductor device according to the present embodiment may be substantially the same as the method described with reference to FIGS. 1, 2, and 4 to 10.

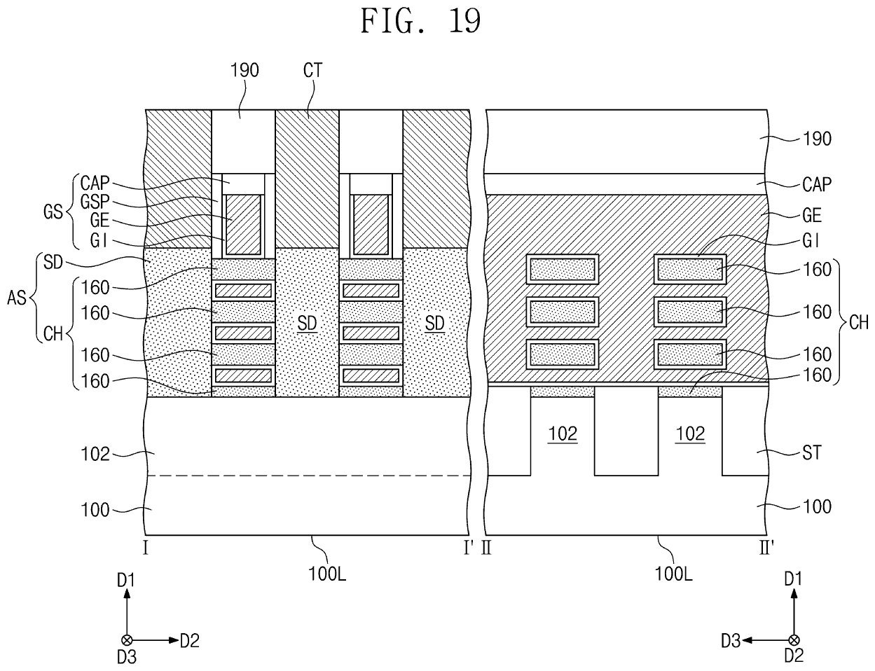

FIG. 19 is a sectional view, which corresponds to the lines I-I′ and II-II′ of FIG. 1 and illustrates a semiconductor device according to some embodiments of the inventive concept. For concise description, an element previously described with reference to FIGS. 1, 2, 3A, and 3B may be identified by the same reference number without repeating an overlapping description thereof.

Referring to FIG. 19, the spacer patterns 150 described with reference to FIGS. 1, 2, 3A, and 3B may be omitted from the semiconductor devices according to some embodiments of the inventive concept. The gate insulating pattern GI may be interposed between each of the source/drain patterns SD and the gate electrode GE, and each of the source/drain patterns SD may be in contact with the gate insulating pattern GI.

The semiconductor patterns 160 of the channel pattern CH may be formed of or may include the same semiconductor material as each other. Each of the semiconductor patterns 160 may include germanium (Ge). For example, each of the semiconductor patterns 160 may include or may be formed of a silicon germanium (SiGe) alloy. Each of the semiconductor patterns 160 may include first portions 160P1, which are overlapped with the gate spacers GSP vertically (e.g., in the first direction D1), and a second portion 160P2, which is provided between the first portions 160P1, as described with reference to FIGS. 12A and 12B. The first portions 160P1 of each of the semiconductor patterns 160 may include germanium (e.g., a silicon germanium (SiGe) alloy), and the second portion 160P2 of each of the semiconductor patterns 160 may also include germanium (e.g., a silicon germanium (SiGe) alloy). For example, each of the semiconductor patterns 160 may be formed of a single material (e.g., a silicon germanium (SiGe) alloy).

Each of the semiconductor patterns 160 may have a thickness in the first direction D1. In some embodiments, unlike the structure shown in FIG. 12A, the thickness 160T1 of the first portions 160P1 of the uppermost semiconductor pattern 160U of the semiconductor patterns 160 may be equal to the thickness 160T2 of the second portion 160P2 of the uppermost semiconductor pattern 160U. The top surfaces 160P1_U of the first portions 160P1 of the uppermost semiconductor pattern 160U may be located at the same height as the top surface 160P2_U of the second portion 160P2 of the uppermost semiconductor pattern 160U, when measured from the substrate 100, and the bottom surfaces 160P1_L of the first portions 160P1 of the uppermost semiconductor pattern 160U may be located at the same height as the bottom surface 160P2_L of the second portion 160P2 of the uppermost semiconductor pattern 160U, when measured from the substrate 100. In some embodiments, as shown in FIG. 12B, the thickness 160T1 of the first portions 160P1 of each of the remaining ones of the semiconductor patterns 160 may be equal to the thickness 160T2 of the second portion 160P2 of each of the remaining semiconductor patterns 160. The top surfaces 160P1_U of the first portions 160P1 of each of the remaining semiconductor patterns 160 may be positioned at the same height as the top surface 160P2_U of the second portion 160P2 of each of the remaining semiconductor patterns 160, when measured from the substrate 100, and the bottom surfaces 160P1_L of the first portions 160P1 of each of the remaining semiconductor patterns 160 may be positioned at the same height as the bottom surface 160P2_L of the second portion 160P2 of each of the remaining semiconductor patterns 160, when measured from the substrate 100. Except for the afore-described differences, the semiconductor patterns 160 may be substantially the same as the semiconductor patterns 160 described with reference to FIGS. 11, 12A, and 12B.

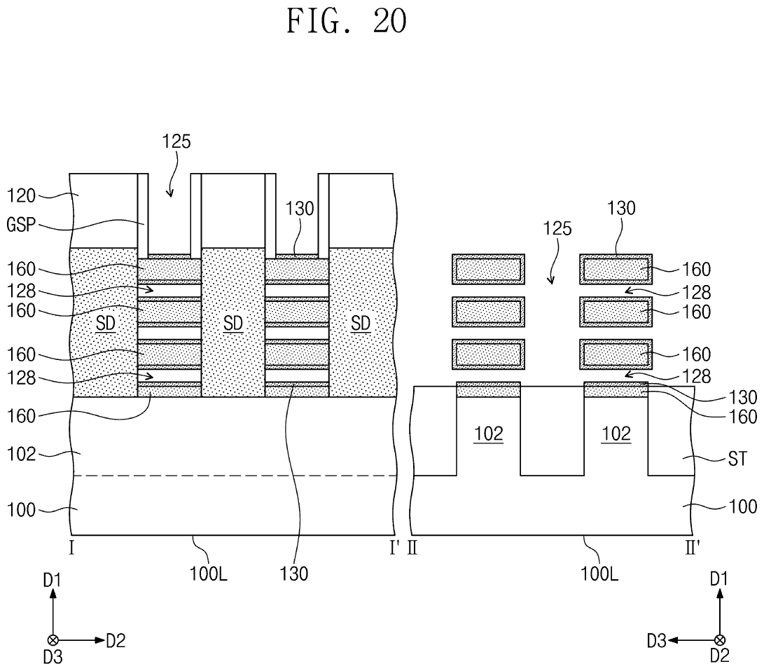

FIG. 20 is a sectional view, which corresponds to the lines I-I′ and II-II′ of FIG. 1 and illustrates a method of fabricating a semiconductor device, according to some embodiments of the inventive concept. For concise description, an element or step previously described with reference to FIGS. 4 to 10 may be identified by the same reference number without repeating an overlapping description thereof.

As described with reference to FIGS. 1 and 8, the sacrificial gate pattern 112 and the etch stop pattern 110 may be removed to form a gap region 125 in the first interlayer insulating layer 120. The sacrificial patterns 104P exposed by the gap region 125 may be selectively removed. Accordingly, empty regions 128 may be formed between the preliminary semiconductor patterns 106P and between the lowermost one of the preliminary semiconductor patterns 106P and the base active pattern 102. The empty regions 128 may be connected to the gap region 125 thus the empty regions 128 and the gap region 125may be connected to each other. In some embodiments, the formation of the spacer patterns 150 may be omitted.

The gap region 125 and the empty regions 128 may be formed to expose not only top and bottom surfaces of the preliminary semiconductor patterns 106P but also the top surface of the base active pattern 102. In some embodiments, the trimming process of recessing the exposed top and bottom surfaces of the preliminary semiconductor patterns 106P and the exposed top surface of the base active pattern 102 may be omitted.

Referring to FIGS. 1 and 20, a germanium layer 130 may be formed on the preliminary semiconductor patterns 106P and the base active pattern 102 exposed by the gap region 125 and the empty regions 128. The germanium layer 130 may be formed on the exposed top and bottom surfaces of the preliminary semiconductor patterns 106P and the exposed top surface of the base active pattern 102.

A thermal treatment process may be performed, after the formation of the germanium layer 130. As a result of the thermal treatment process, germanium (Ge) atoms in the germanium layer 130 may react with the preliminary semiconductor patterns 106P and an upper portion of the base active pattern 102. Accordingly, the preliminary semiconductor patterns 106P and the upper portion of the base active pattern 102 may be converted to semiconductor patterns 160. Each of the semiconductor patterns 160 may be formed of or may include a silicon germanium (SiGe) alloy.

Except for the afore-described difference, the method of fabricating a semiconductor device according to the present embodiment may be substantially the same as the method described with reference to FIGS. 1, 2, and 4 to 10.

A semiconductor device according to an embodiment of the inventive concept may have a negative capacitance (NC) FET using a negative capacitor. As an example, the gate insulating pattern GI may include a ferroelectric layer having a ferroelectric material property and a paraelectric layer having a paraelectric material property. The ferroelectric layer may have a negative capacitance, and the paraelectric layer may have a positive capacitance. In the case where two or more capacitors are connected in series and each capacitor has a positive capacitance, a total capacitance may be less than a capacitance of each of the capacitors. By contrast, in the case where at least one of serially-connected capacitors has a negative capacitance, a total capacitance of the serially-connected capacitors may have a positive value and may be greater than an absolute value of each capacitance. In the case where a ferroelectric layer having a negative capacitance and a paraelectric layer having a positive capacitance are connected in series, a total capacitance of the serially-connected ferroelectric and paraelectric layers may be increased. Due to such an increase of the total capacitance, a transistor including the ferroelectric layer may have a subthreshold swing (SS) less than 60 mV/decade, at the room temperature.

The ferroelectric layer may have a ferroelectric material property. The ferroelectric layer may be formed of or may include at least one of, for example, hafnium oxide, hafnium zirconium oxide, barium strontium titanium oxide, barium titanium oxide, and lead zirconium titanium oxide. For example, the hafnium zirconium oxide may be hafnium oxide that is doped with zirconium (Zr). Alternatively, the hafnium zirconium oxide may be a compound composed of hafnium (Hf), zirconium (Zr), and/or oxygen (O). The ferroelectric layer may further include (i.e., may be doped with) dopants. For example, the dopants may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). The kind of the dopants in the ferroelectric layer may vary depending on a ferroelectric material included in the ferroelectric layer. In the case where the ferroelectric layer includes or is formed of hafnium oxide, the dopants in the ferroelectric layer may include at least one of, for example, gadolinium (Gd), silicon (Si), zirconium (Zr), aluminum (Al), and yttrium (Y). In the case where the dopants are aluminum (Al), a content of aluminum in the ferroelectric layer may have a value between 3 at % and 8 at % (atomic percentage). For example, the content of the aluminum as the dopants may be a ratio of the number of aluminum atoms to the number of hafnium and aluminum atoms. In the case where the dopants are silicon (Si), a content of silicon in the ferroelectric layer may have a value between 2 at % and 10 at %. In the case where the dopants are yttrium (Y), a content of yttrium in the ferroelectric layer may have a value between 2 at % and 10 at %. In the case where the dopants are gadolinium (Gd), a content of gadolinium in the ferroelectric layer may have a value between 1 at % and 7 at %. In the case where the dopants are zirconium (Zr), a content of zirconium in the ferroelectric layer may have a value between 50 at % and 80 at %.

The paraelectric layer may have a paraelectric material property. The paraelectric layer may be formed of or may include at least one of, for example, silicon oxide, and a high-k metal oxide. The metal oxide, which may be used as the paraelectric layer, may include at least one of, for example, hafnium oxide, zirconium oxide, and aluminum oxide, but the inventive concept is not limited to these examples.

The ferroelectric layer and the paraelectric layer may be formed of or may include the same material. The ferroelectric layer may have the ferroelectric material property, but the paraelectric layer may not have the ferroelectric material property. For example, in the case where the ferroelectric and paraelectric layers contain hafnium oxide, a crystal structure of the hafnium oxide in the ferroelectric layer may be different from a crystal structure of the hafnium oxide in the paraelectric layer.

The ferroelectric layer may exhibit the ferroelectric material property, only when it is in a specific range of thickness. In an embodiment, the ferroelectric layer may have a thickness ranging from 0.5 to 10 nm, but the inventive concept is not limited to this example. Since a critical thickness associated with the occurrence of the ferroelectric material property varies depending on the kind of the ferroelectric material, the thickness of the ferroelectric layer may be changed depending on the kind of the ferroelectric material. In an embodiment, the gate insulating pattern GI may include or may be formed of a single ferroelectric layer. Alternatively, the gate insulating pattern GI may include a plurality of ferroelectric layers spaced apart from each other. The gate insulating pattern GI may have a stacking structure, in which a plurality of ferroelectric layers and a plurality of paraelectric layers are alternately stacked.

According to an embodiment of the inventive concept, each of semiconductor patterns constituting a channel pattern may be formed of a single material (e.g., a silicon germanium (SiGe) alloy). Due to this structure of the channel pattern, it may be possible to improve a mobility property of a transistor. Each of the semiconductor patterns may be formed to have a relatively thin thickness. Accordingly, it may be possible to easily reduce a size of the transistor and thereby to easily increase an integration density of a semiconductor device including the transistor.

While example embodiments of the inventive concept have been particularly shown and described, it will be understood by one of ordinary skill in the art that variations in form and detail may be made therein without departing from the spirit and scope of the attached claims.

What is claimed is:

1. A method of fabricating a semiconductor device, comprising:
forming an active pattern on a substrate, the active pattern comprising a plurality of sacrificial patterns and a plurality of preliminary semiconductor patterns, which are alternatively stacked in a first direction perpendicular to a top surface of the substrate;
removing the plurality of sacrificial patterns to form a plurality of empty regions between the plurality of preliminary semiconductor patterns;
forming a germanium layer on the plurality of preliminary semiconductor patterns exposed by the plurality of empty regions;
performing a thermal treatment process on the plurality of preliminary semiconductor patterns provided with the germanium layer to convert the plurality of preliminary semiconductor patterns to a plurality of semiconductor patterns; and
removing the germanium layer, which remains on the plurality of semiconductor patterns after the converting of the plurality of preliminary semiconductor patterns to the plurality of semiconductor patterns,
wherein each of the plurality of semiconductor patterns comprises germanium.

2. The method of claim 1,
wherein each of the plurality of preliminary semiconductor patterns comprises silicon, and
wherein each of the plurality of semiconductor patterns comprises a silicon germanium alloy.

3. The method of claim 1, further comprising:
recessing a surface of each of the plurality of preliminary semiconductor patterns exposed by a corresponding one of the plurality of empty regions,
wherein the germanium layer is formed on the recessed surface of each of the plurality of preliminary semiconductor patterns.

4. The method of claim 3, further comprising:
forming a sacrificial gate pattern on the active pattern and a pair of gate spacers covering opposite side surfaces of the sacrificial gate pattern, respectively; and
removing the sacrificial gate pattern to form a gap region between the pair of gate spacers,
wherein the gap region is formed to expose an uppermost preliminary semiconductor pattern of the plurality of preliminary semiconductor patterns, and
wherein the recessing of the surface of each of the plurality of preliminary semiconductor patterns comprises recessing a surface of the uppermost preliminary semiconductor pattern exposed by the gap region.

5. The method of claim 4,
wherein each semiconductor pattern of the plurality of semiconductor patterns comprises a pair of first portions, which are vertically overlapped with the pair of gate spacers, respectively, and a second portion between the pair of first portions, and
wherein each of the plurality of semiconductor patterns includes the second portion with a first thickness, and the pair of first portions with a second thickness which is greater than the first thickness.

6. The method of claim 1,
wherein in the forming of the germanium layer, the germanium layer is selectively formed on the plurality of preliminary semiconductor patterns exposed by the plurality of empty regions.

7. A method of fabricating a semiconductor device, comprising:
forming an active pattern on a substrate, the active pattern comprising a plurality of sacrificial patterns and a plurality of preliminary semiconductor patterns, which are alternatively stacked in a first direction perpendicular to a top surface of the substrate;
forming a sacrificial gate pattern on the active pattern;
forming gate spacers on side surfaces of the sacrificial gate pattern;
forming spacer patterns on side surfaces of each sacrificial pattern of the plurality of sacrificial patterns;
forming source/drain patterns on side surfaces of the active pattern, the plurality of sacrificial patterns, the plurality of preliminary semiconductor patterns and the spacer patterns being between the source/drain patterns;
removing the sacrificial gate pattern to form a gap region between the gate spacers;
removing the plurality of sacrificial patterns to form a plurality of empty regions between the plurality of preliminary semiconductor patterns and between the spacer patterns;
forming a germanium layer on the plurality of preliminary semiconductor patterns exposed by the plurality of empty regions; and
performing a thermal treatment process to convert the plurality of preliminary semiconductor patterns to a plurality of semiconductor patterns,
wherein each semiconductor of the plurality of semiconductor patterns comprises germanium.

8. The method of claim 7,
wherein each of the plurality of preliminary semiconductor patterns comprises silicon, and
wherein each of the plurality of semiconductor patterns comprises a silicon germanium alloy.

9. The method of claim 7, further comprising:
recessing a surface of each of the plurality of preliminary semiconductor patterns exposed by a corresponding one of the plurality of empty regions,
wherein the germanium layer is formed on the recessed surface of each of the plurality of preliminary semiconductor patterns.

10. The method of claim 7, further comprising:
removing the germanium layer, which remains on the plurality of semiconductor patterns after the thermal treatment process.

11. The method of claim 7,
wherein the forming of the germanium layer comprises performing a selective growth process using the plurality of preliminary semiconductor patterns as a seed layer.

12. The method of claim 7, further comprising:
forming a gate insulating pattern and a gate electrode to fill the gap region and the plurality of empty regions.

13. A method of fabricating a semiconductor device, comprising:
forming an active pattern on a substrate, the active pattern comprising a plurality of sacrificial patterns and a plurality of preliminary semiconductor patterns, which are alternatively stacked in a first direction perpendicular to a top surface of the substrate;
forming a sacrificial gate pattern on the active pattern;
forming gate spacers on the active pattern and on side surfaces of the sacrificial gate pattern;
forming spacer patterns on side surfaces of each sacrificial pattern of the plurality of sacrificial patterns;
removing the sacrificial gate pattern to form a gap region between the gate spacers;
removing the plurality of sacrificial patterns to form a plurality of empty regions between the plurality of preliminary semiconductor patterns and between the spacer patterns;
forming a germanium layer on the plurality of preliminary semiconductor patterns exposed by the plurality of empty regions and the gap region; and
performing a thermal treatment process to convert the plurality of preliminary semiconductor patterns to a plurality of semiconductor patterns,
wherein each semiconductor pattern of the plurality of semiconductor patterns comprises germanium.

14. The method of claim 13,
wherein each semiconductor pattern of the plurality of semiconductor patterns comprises a silicon germanium alloy.

15. The method of claim 13, further comprising:
recessing a surface of each of the plurality of preliminary semiconductor patterns exposed by the plurality of empty regions and the gap region,
wherein the germanium layer is formed on the recessed surface of each preliminary semiconductor pattern of the plurality of preliminary semiconductor patterns.

16. The method of claim 13,
wherein the forming of the germanium layer comprises performing a selective growth process using the plurality of preliminary semiconductor patterns as a seed layer.

17. The method of claim 13, further comprising:
removing the germanium layer, which remains on the plurality of semiconductor patterns after the thermal treatment process.

18. The method of claim 17, further comprising:
forming a gate insulating pattern to cover inner surfaces of the gap region and the plurality of empty regions, and
forming a gate electrode to fill remaining spaces of the gap region and the plurality of empty regions.

19. The method of claim 13,
wherein the sacrificial gate pattern and the gate spacers overlap with the active pattern in the first direction.

20. The method of claim 13,
wherein the spacer patterns overlap with cach of the plurality of sacrificial patterns in a second direction parallel to the top surface of the substrate.
